(19) United States
(12) Patent Application Publication
(10) Pub. No.: US 2026/0051353 A1
(43) Pub. Date: Feb. 19, 2026

(54) Reprogrammable physically unclonable function block

(71) Applicant: ANAFLASH INC., Sunnyvale, CA (US)

(72) Inventors: Seung-Hwan Song, Palo Alto, CA (US); Pirooz Parvarandeh, Los Altos Hills, CA (US)

(21) Appl. No.: 19/296,544

(22) Filed: Aug. 11, 2025

Related U.S. Application Data
(60) Provisional application No. 63/682,766, filed on Aug. 13, 2024.

(51) Int. Cl. G11C 16/22; G11C 16/10; G11C 16/24; G11C 16/26

(52) U.S. Cl. CPC G11C 16/22; G11C 16/102; G11C 16/24; G11C 16/26

(57) ABSTRACT

A non-volatile memory device comprises: a memory cell array with a plurality of non-volatile memory cells; a security key producing circuitry coupled to each column of the memory cell array, the security key producing circuitry configured to perform a series of erase, read, and program operations on a group of the plurality of memory cells to generate a device-specific security key of the memory device, wherein the security key producing circuitry is configured to: erase the group of the memory cells and read erased memory states varied by different physical processing variations of sub-units of each memory cell of the group; and selectively program the sub-units of the erased memory cell based on the erased memory states of the sub-units such that resulting patterns of the programmed states of the erased sub-units are encoded into a permanent, non-volatile digital key.

### CROSS-REFERENCE TO RELATED APPLICATIONS

This application claims priority to and the benefit of Provisional U.S. Patent Application No. 63/682,766, filed on Aug. 13, 2024. This application is related to U.S. patent application Ser. No. 16/196,617 filed on Nov. 20, 2018, now U.S. Pat. No. 11,361,215. This application is also related to U.S. patent application Ser. No. 16/252,640 filed on Jan. 20, 2019, now U.S. Pat. No. 11,361,216. These applications are incorporated herein in their entirety by this reference.

### FIELD OF THE INVENTION

The invention generally relates to the field of semiconductor device security, and more specifically to a reprogrammable physically unclonable function (PUF) structure capable of generating and securely updating unique identifiers on an integrated circuit. The reprogrammable physically unclonable function is a building block to generate a unique key parameter of an individual silicon chip using a non-volatile flash memory. This disclosure relates to a reprogrammable PUF capable of storing and updating its value by reprogramming, when necessary, which can replace conventional one-time programmable PUFs.

### BACKGROUND OF THE INVENTION

In today's interconnected world, ensuring the security and trustworthiness of electronic devices is of paramount importance. Integrated circuits (ICs), which are the core of nearly all modern electronics, require robust mechanisms for authentication, secure data storage, and cryptographic operations. A critical component of hardware security is the ability to generate a unique identity for each individual chip, effectively giving it an unclonable “fingerprint.” This unique identity can then serve as a root of trust for various security applications, including secure boot, device authentication, and the generation of cryptographic keys.

A physically unclonable function, or PUF, has emerged as a promising hardware security primitive for this purpose. A PUF is a physical entity embodied in a physical structure that is easy to fabricate but practically impossible to duplicate, even by the original manufacturer. The function of a PUF relies on the inherent and uncontrollable variations that occur during the semiconductor manufacturing process. These microscopic variations, such as random fluctuations in dopant concentrations, gate oxide thickness, and interconnect wire widths, result in unique physical and electrical characteristics for each transistor and wire on a chip. While manufacturers strive to minimize these variations to ensure consistent device performance, they cannot be eliminated entirely. A PUF leverages these deep sub-micron process variations to create a unique and repeatable response for each individual IC.

The operational principle of a PUF is typically based on a challenge-response mechanism. When a specific input, known as a “challenge,” is applied to the PUF circuit, it produces a corresponding output, known as a “response,” which is determined by the unique physical characteristics of that specific chip. For the same challenge, a given PUF will reliably produce the same response, but it is computationally infeasible to predict the response without having physical access to the specific PUF instance. This challenge-response behavior makes PUFs an excellent building block for generating secret keys. Such key information is often used for encrypting data to be transferred securely.

Various types of PUFs have been developed, including SRAM PUFs, which exploit the random power-up state of SRAM cells, and Ring Oscillator PUFs, which utilize frequency variations in identical oscillator circuits. Another class of PUFs is based on memory structures, where the initial, random state of memory cells after fabrication is used as the source of randomness. For example, in flash memory technology, the threshold voltage (Vth) of each memory cell can have a stochastic distribution due to the random number of electrons initially stored in its floating gate and other physical variations. By comparing the electrical properties (e.g., cell current) of a pair of such memory cells, a random digital bit (0 or 1) can be generated.

While PUFs offer a powerful method for creating unique chip identities, they are not without challenges. A primary issue is the stability and reliability of the PUF response. The response can be sensitive to environmental variations such as temperature, voltage fluctuations, and circuit aging. This can lead to bit-flips in the response, where a PUF produces a slightly different output for the same challenge under different operating conditions. To address this, complex error-correction codes (ECC) and “helper data” schemes are often employed to reconstruct the original, noise-free response. However, these schemes add significant area and power overhead, and the helper data itself may leak partial information about the secret key, creating a potential security vulnerability.

To ensure the generated key remains unchanged and reliable during the lifetime of the chip, a common industry practice is to generate the PUF key once during device enrollment and then store it permanently in a one-time programmable (OTP) non-volatile memory (NVM). This approach effectively “hardens” the noisy PUF response into a stable, reliable key. However, this method introduces a significant and critical security risk. The challenge in this scenario is that the key information cannot be changed after the stored value is known to somewhere else. If the secret key is compromised at any point during the chip's lifecycle, due to a side-channel attack, reverse engineering, or a data breach, the device is permanently and irreversibly compromised. Since the key is stored in an OTP memory, there is no mechanism to revoke the old key and issue a new one. The device's root of trust is broken, and it can no longer be considered secure.

This limitation highlights a fundamental conflict in current hardware security practices: the need for a stable, permanent identity versus the need for a revocable identity in case of a security breach. A physical key that is permanent offers reliability but is brittle in the face of compromise. A key that can be updated offers resilience but often relies on less secure external key management infrastructures.

Therefore, there is a clear and unmet need for a hardware security solution that bridges this gap. A desirable solution would provide the benefits of a PUF, an intrinsic, unclonable, and unique hardware fingerprint, while also offering the flexibility to securely erase and regenerate the identity if it is ever compromised. Such a reprogrammable PUF would allow the value to be stored and updated whenever reprogramming is necessary, ensuring the PUF value is securely managed throughout the entire lifetime of the chip. This would significantly enhance the long-term security and resilience of electronic devices in a constantly evolving threat landscape.

### SUMMARY OF INVENTION

This invention discloses a semiconductor device-specific security key generating device, and more specifically to a reprogrammable physically unclonable function (PUF) structure capable of generating and securely updating unique identifiers on an integrated circuit.

According to the present invention, a non-volatile memory device comprises a memory cell array with a plurality of non-volatile memory cells; a security key producing circuitry coupled to each column of the memory cell array, the security key producing circuitry configured to perform a series of erase, read, and program operations on a group of the plurality of memory cells to generate a device-specific security key of the memory device, wherein the security key producing circuitry is configured to: erase the group of the memory cells and read erased memory states varied by different physical processing variations of sub-units of each memory cell of the group; and selectively program the sub-units of the erased memory cell based on the erased memory states of the sub-units such that resulting patterns of the programmed states of the erased sub-units are encoded into a permanent, non-volatile digital key.

In one embodiment, the non-volatile memory cells are coupled to a plurality of input voltage lines and coupled to respective pairs of complementary bitlines, each memory cell including a pair of identical sub-units, each sub-unit including a pair of floating gates.

In one embodiment, the pairs of complementary bitlines are connected to the security key producing circuitry.

In one embodiment, the security key producing circuitry comprises a plurality of sensing circuits in parallel, each sensing circuit coupled to each column of the memory cell array.

In one embodiment, each sensing circuit is configured to read states of sub-units in each memory cell through one of the pairs of complementary bit lines.

In one embodiment, the sensing circuit is configured to detect which bitline in each pair of the complementary bit lines has a higher or a lower current value by comparing their current values relative to each other during a process of reading the sub-units of the erased memory cells.

In one embodiment, the sensing circuit comprises: a differential amplifier configured to convert a pair of current values of the complementary bitline into a pair of complementary digital values; a pair of input paths for the differential amplifier to receive the pair of current values of the complementary bitlines; a pair of output paths for the differential amplifier to output the pair of complementary digital values; and a pair of buffer circuits between the input paths and the output paths, creating feedback paths for supplying the pair of complementary digital values to the complementary bitlines, wherein the feedback paths are configured to bias the complementary bitlines during a program operation, thereby selectively programming a first one of the pair of sub-units while inhibiting programming of a second one of the pair based on the complementary digital output signals.

In one embodiment, the differential amplifier comprises: a comparator configured to: receive the pair of current values of the complementary bitlines connected to the sub-units within an associated said memory cell; detect which one of the sub-units has a higher or lower current value; and convert a pair of current values of the complementary bitlines coupled to the sub-units in each memory cell into corresponding digital values such that the sub-unit with a higher current value is converted into a digital logic “1”, and the sub-unit with a lower current value is converted into a digital logic “0”; and a latch circuit configured to store the converted digital values of the sub-units of the memory cells.

In one embodiment, the latch circuit is coupled to the pair of the output paths, outputting a binary 1 signal in response to the first input current signal greater than the second input current signal and outputting a binary 0 signal in response to the second input current signal lower than the first input current signal.

In one embodiment, deactivated said buffer circuit pair prevents feedback of output signals to the inputs of the differential amplifier and allows inputting of currents flowing through complementary bitlines during the read operation.

In one embodiment, activated said buffer circuit pair creates feedback loops for inputting the converted digital data values stored in the latch circuit to bias the complementary bitlines of the memory cell during the program operation.

In one implementation of the present invention, in a non-volatile memory device having (1) a memory cell array with a plurality of nonvolatile memory cells in parallel, having their source electrodes coupled together into a combined source line, (2) pairs of complementary bitlines coupled to respective pairs of sub-units within each memory cell, and (3) a sensing device coupled to columns of the memory cell array, a method of creating a device-specific security key comprises: (a) applying a set of predefined erase voltages to pairs of sub-units of a group of non-volatile memory cells in parallel; (b) read erased memory states of the pair of sub-units by applying a set of predefined read voltages to the erased nonvolatile memory cells in parallel; (c) comparing different current values of the pair of sub-units from the erased nonvolatile memory cells in parallel; (d) programming a first sub-unit of the pair having a lower current value while preventing a second sub-unit of the pair having a higher current value from being programmed; and (c) repeating (a) to (d) one or more times to create a permanent, non-volatile digital key.

In one implementation, the step (b) is performed by a sensing device that comprises a group of sensing circuits in parallel coupled to respective columns of the memory cell array.

In one implementation, the step (c) further comprises converting a pair of current values of the complementary bitline for each memory cell into a pair of corresponding complementary digital values.

In one implementation, the step (d) includes converting a pair of current values of the complementary bitlines coupled to the sub-units in each memory cell into corresponding digital values such that the sub-unit with a higher current value is converted into a digital logic “1”, and the sub-unit with a lower current value is converted into a digital logic “0”.

In one implementation, the step (d) further includes creating feedback paths for supplying the pair of complementary digital values to the complementary bitlines, wherein the feedback paths bias the pair of complementary bitlines during a program operation, thereby selectively programming a first one of the pair of sub-units while inhibiting programming of a second one of the pair based on the complementary digital output signals.

In one embodiment, each of the plurality of memory cells includes a floating gate. Additional features and advantages of the present invention will be understood from the following description of its preferred embodiments, which description should be taken in conjunction with the accompanying drawings.

### BRIEF DESCRIPTION OF THE DRAWINGS

The following drawing parts of the specification are included to further demonstrate certain embodiments or various aspects of the invention. In some instances, embodiments of the invention can be best understood by referring to the accompanying drawings in combination with the detailed description presented herein. The description and accompanying drawings may highlight a specific example or aspect of the invention. However, one skilled in the art will understand that portions of the example or aspect may be used in combination with other examples or aspects of the invention.

FIG. 1 shows a macro block of a proposed reprogrammable PUF (Physically Unclonable Function).

FIG. 2 illustrates a schematic circuit of a single reprogrammable PUF cell according to an embodiment of the present invention.

FIG. 3 illustrates a schematic diagram of a sensing circuit in accordance with a preferred embodiment of the present invention.

FIG. 4 is a conceptual graph illustrating the initial statistical distribution of the threshold voltage (Vth) of the PUF half-cells.

FIG. 5 illustrates a schematic circuit with the biasing conditions applied to the PUF cell for an erase operation.

FIG. 6 is a graph illustrating the statistical distribution of the half-cell threshold voltages after the erase operation.

FIG. 7 illustrates a schematic circuit with the biasing conditions applied to the PUF cell for a read operation.

FIG. 8 shows the operational biasing of the sensing circuit during a read or sense cycle.

FIG. 9 illustrates the configuration of the sensing circuit to initiate a reprogramming or hardening process.

FIG. 10 illustrates the specific biasing conditions applied to the PUF cell to perform a hardening operation.

FIG. 11 is a conceptual graph illustrating the final distribution of the half-cell threshold voltages.

### DETAILED DESCRIPTION OF THE INVENTION

In the following detailed description of the invention, reference is made to the accompanying drawings that form a part hereof, and in which is shown by way of illustration a specific embodiment in which the invention may be practiced. In the drawings, like numerals and characters refer to like elements throughout the several views. It is to be understood that other embodiments may be utilized and structural or logical changes may be made without departing from the scope of the present invention. The following detailed description is, therefore, not to be taken in a limiting sense, and the scope of the present invention is defined by the appended claims.

It will be understood that when an element or layer is referred to as being “on”, “connected to” or “coupled to” another element or layer, it can be directly on, connected to, or coupled to the other element or layer or intervening elements or layers may be present. In contrast, when an element is referred to as being “directly connected to” or “directly coupled to” another element or layer, there are no intervening elements or layers present.

It will be understood that, although the terms first, second, third, etc. may be used herein to describe various elements, components, regions, and/or sections, these elements, components, regions, and/or sections should not be limited by these terms. These terms are only used to distinguish one element, component, region, or section from another. Thus, a first element, component, region, or section discussed below could be termed a second element, component, region, or section without departing from the teachings of the present invention.

The terminology used herein is to describe particular embodiments only and is not intended to be limiting of the invention. As used herein, the singular forms “a”, “an”, and “the” are intended to include the plural forms as well, unless the context indicates otherwise. It will be further understood that the term “comprising” or “comprises,” when used in this specification, specifies the presence of stated features, integers, steps, operations, elements, and/or components, but does not preclude the presence or addition of one or more other features, integers, steps, operations, elements, components, and/or groups thereof.

Example embodiments are described herein regarding schematic illustrations. As such, the illustrations are not necessarily drawn to scale, and variations from the shapes and connections of the illustrations as a result, for example, of manufacturing techniques and/or tolerances, are to be expected. The figures are schematic in nature and their shapes are not intended to illustrate the actual implementation of a device and are not intended to limit the scope of the invention. For example, the circuit diagrams are intended to illustrate the electrical connectivity and functional relationship between components, not necessarily their physical placement or layout on a silicon die. Similarly, the graphs depicting distributions are conceptual and serve to illustrate the principles of the invention rather than representing precise empirical data.

Furthermore, it will be understood that terms used to describe voltage or signal levels, such as “high” and “low,” are relative. A “high” level may refer to a standard supply voltage (e.g., VDD) or a higher programming/erasing voltage (e.g., VPP), while a “low” level typically refers to a ground potential (e.g., GND), as will be apparent from the context of the specific operation being described.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

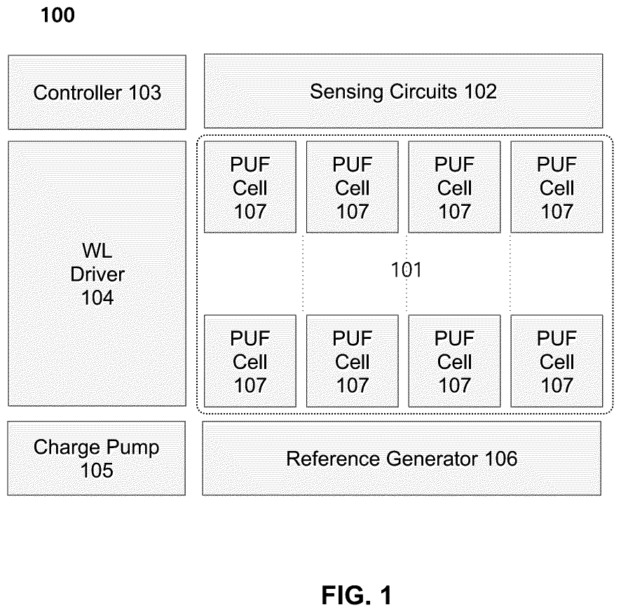

FIG. 1 shows a proposed PUF macro block 100 consisting of a reprogrammable PUF cell array 101, a sensing circuit 102, a controller 103, WL driver 104, a charge pump 105, and a reference generator 106. Any of these circuits can be built using standard logic devices without any process overhead. The PUF macro block 100 is a self-contained system on an integrated circuit designed to generate, store, and securely manage a unique hardware-based key. Each component block plays a critical role in the overall operation of the device.

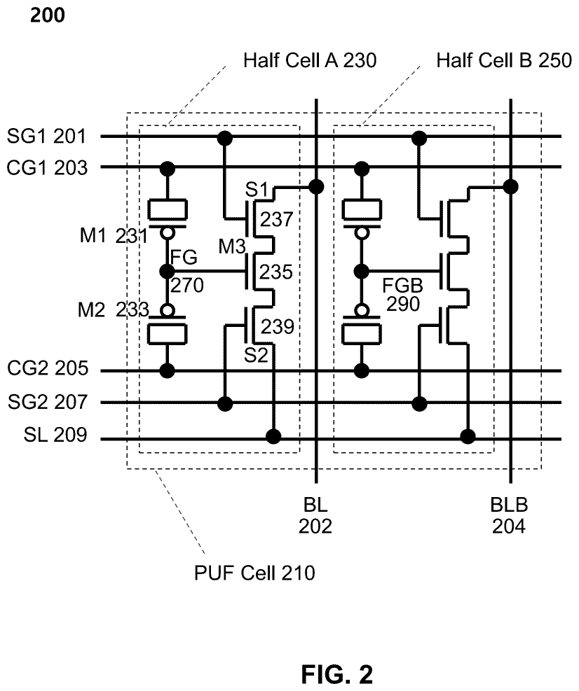

The PUF Cell Array 101 is centrally located and comprises a plurality of individual PUF cells 107 arranged in a two-dimensional array of rows and columns. Each PUF cell 107 is the fundamental unit for generating a random bit based on intrinsic physical variations from the manufacturing process. The collective responses of the cells in the array form a unique digital fingerprint for the chip. The detailed schematic and operational principles of a single PUF cell 107 will be described later with reference to FIG. 2.

The Controller 103 is the central logic unit that governs the overall functionality of the PUF macro block 100. It orchestrates the complex interactions between all other components to ensure one or more proper operations during read, program, and erase cycles. For example, the Controller 103 communicates with the Charge Pump 105 to apply a predetermined high voltage to the PUF cells 107 at the precise time required for programming or erasing. It manages the WL (Word Line) Driver 104 to apply word line signals with appropriate voltage levels and timing to select specific cells within the array. Furthermore, the Controller 103 enables the Sensing Circuits 102 to accurately capture the state of the PUF cells 107 and directs the Reference Generator 106 to provide stable reference signals needed for reliable sensing operations.

The Sensing Circuits 102 are communicatively coupled to the PUF Cell Array 101 and are responsible for reading the state of the individual PUF cells 107. During a read operation, the Sensing Circuits 102 receive analog signals (e.g., cell currents) from a PUF cell 107, which typically consists of a pair of half-cells as will be detailed in FIG. 2. The circuits are configured to differentially compare these signals, determine their relative magnitude (i.e., which signal is larger or smaller), and amplify this small difference into a full-swing digital logic level (e.g., a ‘0’ or ‘1’).

The WL Driver 104 is configured to generate and apply various word line signals to the PUF Cell Array 101. These signals, provided with specific voltages and timing as dictated by the Controller 103, are used to select the desired row of PUF cells 107 for a given operation, such as reading, programming, or erasing.

The Charge Pump 105 is a voltage-boosting circuit responsible for generating a high voltage that is significantly higher than the standard supply voltage (VDD) of the chip. This high voltage is essential for programming and erasing operations in the PUF cells 107, which rely on high electric fields to inject or remove electrons from a floating gate structure.

The Reference Generator 106 is configured to generate stable and precise reference signals, such as reference voltages or currents. These reference signals are utilized by the Sensing Circuits 102 and other analog portions of the macro block 100 to ensure that read and comparison operations are consistent and reliable across varying process, voltage, and temperature (PVT) conditions.

### Examples of PUF Cell

FIG. 2 illustrates a detailed circuit schematic 200 of a single reprogrammable PUF cell, according to an embodiment of the invention. As mentioned previously, the PUF Cell Array 101 in FIG. 1 comprises a plurality of these PUF cells 107. The fundamental principle of the PUF cell 210 is based on a differential structure. As shown in FIG. 2, the PUF cell 210 consists of two identical half-cells, Half Cell A 230 and Half Cell B 250, arranged as a pair. This differential architecture allows for robust sensing of the cell's state by comparing the electrical characteristics of the two constituent half-cells. As Half Cell A 230 and Half Cell B 250 are structurally identical, the following description will detail the composition of Half Cell A 230, and it is to be understood that Half Cell B 250 mirrors this configuration.

Each half-cell includes five transistors (a 5T architecture) implemented using standard logic devices. For clarity in this description, the five transistors of Half Cell A 230 are designated as M1 231, M2 233, S1 237, M3 235, and S2 239.

The transistors M1 231 and M2 233 are PMOS transistors, while transistors S1 237, M3 235, and S2 239 are NMOS transistors. The gates of the first PMOS transistor M1 231, the second PMOS transistor M2 233, and the NMOS read transistor M3 235 are electrically interconnected to form a common floating gate node FG 270. This floating gate FG 270 is electrically isolated by surrounding oxide layers, a critical feature that enables it to trap or release electrons, thereby storing a charge that represents the state of the half-cell.

The first transistor M1 231, a PMOS transistor, functions as a coupling transistor. Its source and drain terminals are coupled together to a first control gate line CG1 203. The second transistor M2 233, also a PMOS transistor, functions as another coupling or erase transistor. Its source and drain terminals are similarly coupled together and connected to a second control gate line CG2 205.

The three NMOS transistors S1 237, M3 235, and S2 239 are connected in series to form a read path for the half-cell. The first select transistor S1 237 has its drain terminal connected to a bit line BL 202 and its gate terminal coupled to a first select gate line SG1 201. The source terminal of S1 237 is coupled to the drain terminal of the read transistor M3 235. The read transistor M3 235, whose gate is part of the floating gate FG 270, has its source terminal coupled to the drain terminal of the second select transistor S2 239. Finally, the second select transistor S2 239 has its gate terminal coupled to a second select gate line SG2 207, and its source terminal is coupled to a common source line SL 209.

As stated, Half Cell B 250 is a counterpart to Half Cell A 230 and possesses an identical 5T structure. It is connected to the same control lines (SG1 201, CG1 203, CG2 205, SG2 207, SL 209) but is coupled to a complementary bit line BLB 204. Internally, Half Cell B 250 has its own common floating gate node, FGB 290, which is formed by the interconnected gates of its respective three transistors in the same manner as Half Cell A 230.

This differential PUF cell 210 structure is fundamental to the invention, enabling the generation of a random bit by precisely comparing the conductance and resulting cell currents of Half Cell A 230 and Half Cell B 250. The detailed principles of operation, including the read, erase, and program (reprogram) biasing conditions, will be described hereinafter with reference to subsequent figures.

### Sensing Circuit

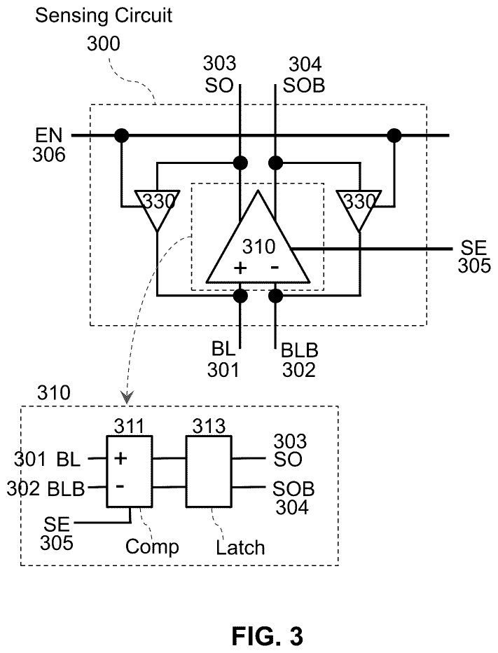

In FIG. 3, a schematic diagram of an exemplary sensing circuit 300 is illustrated, in accordance with an embodiment of the present invention. As described with reference to FIG. 1, the Sensing Circuits 102 block contains a plurality of such sensing circuits 300. In a preferred embodiment, one sensing circuit 300 is provided for each column of the PUF Cell Array 101, receiving differential inputs from that column and generating a digital output corresponding to the state of a selected PUF cell 107 in that column.

The sensing circuit 300 receives as its primary input signals from a complementary bit line pair, the bit line BL 301 and the bit line bar BLB 302, which are connected to a column of the PUF Cell Array 101. Accordingly, when a specific PUF cell within that column is selected for an operation, the bit line BL 202 and complementary bit line BLB 204 of that cell, as shown in FIG. 2, correspond directly to the input lines BL 301 and BLB 302 of the sensing circuit. The sensing circuit 300 generates a pair of complementary digital outputs: sensing out SO 303 and sensing out bar SOB 304. The operation of the sensing circuit 300 is governed by two main control signals: a sense enable signal SE 305 and an enable signal EN 306.

Internally, the core of the sensing circuit is a differential amplifier 310, which can be functionally divided into two primary stages: a comparator stage (Comp 311) and a latch stage (Latch 313). This two-stage design allows for both sensitive detection and stable storage of the PUF cell's state.

The comparator 311 stage is a well-known circuit element, typically implemented using a differential amplifier. It is designed to receive two analog input signals, such as the currents or voltages on the BL and BLB lines, and determine which one is greater. After comparing the inputs, the comparator generates an output that represents the result, providing an initial amplification of the small analog difference between the inputs.

The latch 313 stage is a fundamental digital storage circuit, commonly constructed from a pair of cross-coupled inverters. This structure creates a positive feedback loop, making the circuit bistable. Its function is to receive the amplified signal from the comparator stage, rapidly drive it to a full-swing digital logic level (e.g., VDD or GND), and hold, or ‘latch,’ this state as a stable digital value. This provides the final, stored output of the sensing operation.

The first stage is the comparator 311. Upon activation of the sense enable signal (SE 305), the comparator 311 is configured to differentially read and compare the currents flowing through the BL 301 and BLB 302 lines from a selected PUF cell. Due to the inherent random physical variations in the PUF cell's half-cells, there will be a slight mismatch in their cell currents. The comparator is designed to be highly sensitive to detect this small current difference.

The second stage is the latch 313. The small differential signal detected by the comparator 311 is then amplified and fed into the latch 313 stage. The latch 313 captures this amplified difference and resolves it into a full-swing, complementary digital value, which is then stored and output as SO 303 and SOB 304. For instance, if the current on BL 301 is slightly greater than on BLB 302, SO 303 may be latched to a logic ‘1’ (High) and SOB 304 to a logic ‘0’ (Low), and vice-versa.

A key feature of the proposed sensing circuit 300 is a feedback path designed to enable the reprogramming of the PUF cell. The digital outputs (SO 303 and SOB 304) from the latch 313 stage can be fed back to the input lines (BL 301 and BLB 302) through a set of buffers 330. This feedback operation is controlled by the enable signal EN 306. When the EN 306 signal is activated, the buffers 330 are enabled, driving the latched digital values back onto the bit lines 301, 302 to facilitate a program or “hardening” operation for the connected PUF cell. This mechanism is integral to the “reprogrammable” nature of the disclosed invention.

Having described the physical structure of the PUF macro block 100, the PUF cell 200, and the sensing circuit 300, the description now turns to the inherent electrical characteristics of the device.

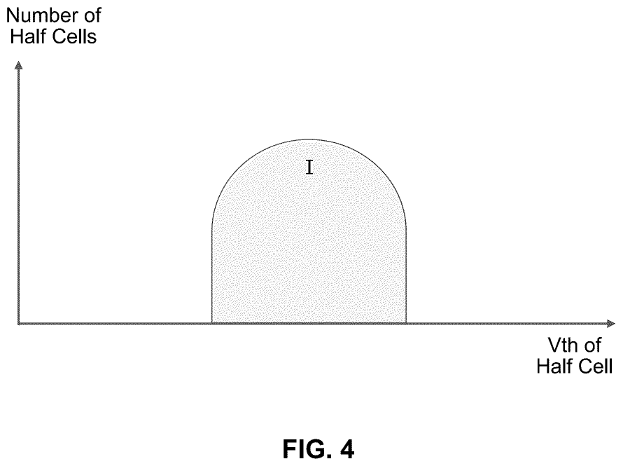

FIG. 4 is a conceptual graph illustrating the initial statistical distribution of the threshold voltage (Vth) of the PUF half-cells across an integrated circuit immediately after fabrication, in accordance with an embodiment of the invention. This graph explains the fundamental principle that enables the PUF to generate a unique identity.

In semiconductor manufacturing, it is practically impossible to fabricate two transistors or two memory cells that are perfectly identical. Despite using the same design layout, inherent and uncontrollable microscopic variations occur throughout the fabrication process. Since the number of electrons stored in a floating gate is initially random and various process parameters such as dopant concentration, gate oxide thickness, and the physical size of the floating gate have a physical variation after fabrication, each half-cell possesses a unique set of electrical characteristics. This means that even before any program or erase operations are performed, the initial amount of residual charge trapped in the floating gate (FG 270) and the intrinsic properties of the read transistor (M3 235) will differ slightly from one half-cell to another.

As a direct consequence of these random physical variations, the effective half-cell Vth, which is the gate voltage required to turn on the read path of the cell, exhibits a stochastic distribution. FIG. 4 graphically represents this phenomenon. The x-axis represents the threshold voltage value of Half cells as described in FIG. 2, and the y-axis represents the number of Half-cells that exhibit that particular Vth value. The resulting bell-shaped curve illustrates that across a large population of the half-cells on a chip; the Vth values are not uniform but are randomly distributed around a mean value. The letter ‘I’ inside the bell-shaped distribution denotes ‘Initial,’ indicating that this graph represents the Vth distribution of the half-cells in their initial state.

This inherent randomness is the source of entropy for the PUF. In addition to these random, localized variations, there can also be larger, systematic variations that occur across the surface of a silicon wafer, known as process gradients. These gradients can cause cells in one area of the chip to have slightly different average characteristics than cells in another area. To mitigate the influence of such systematic effects and enhance the quality of the randomness, the present invention utilizes a differential cell structure, as detailed in FIG. 2. Pairing two half-cells placed in close physical proximity to one another reduces the effects of gradients on a wafer, thereby creating more reliable randomness. Because the two half-cells are adjacent, they are subject to nearly identical process gradients, causing the systematic variations to be largely cancelled out when the cells' currents are compared differentially. This ensures that the unique output of the PUF cell is dominated by the desired local, random variation

Ultimately, it is this inherent and uncontrollable stochastic distribution of half-cell Vth that serves as the fundamental source of entropy, enabling the generation of a unique and unclonable hardware identity for each individual chip. The reprogrammable PUF architecture includes a global erase capability, which can serve as a crucial initialization or reset function.

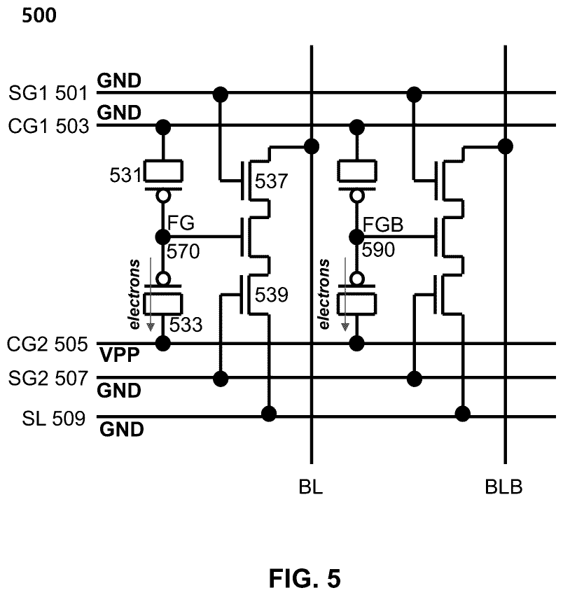

FIG. 5 illustrates the biasing conditions applied to the PUF cell 500 to perform this global erase operation. This operation is designed to uniformly remove the initial, random residual charges from the floating gates (FG 570 and FGB 590) of all half-cells, thereby conditioning the entire array to a known, low-threshold-voltage erased state. This provides a consistent baseline from which a new, secure key can be reliably generated, or serves to securely delete a previously hardened key.

To execute the global erase operation, a specific set of voltages is applied across the PUF cell. A high, positive erase voltage, VPP, is applied to the second control gate line CG2 505. Simultaneously, the first control gate line CG1 503, the first and second select gate lines SG1 501 and SG2 507, and the common source line SL 509 are all coupled to ground potential (GND). These biasing conditions are applied uniformly to both Half Cell A and Half Cell B, as well as all other cells in the array.

The physical mechanism for erasing is as follows. With the select gate lines SG1 501 and SG2 507 held at GND, the select transistors S1 537 and S2 539 are turned off, isolating the read path of the half-cells. The erase process is primarily controlled by the interaction between the control gate lines and the floating gate. The first control gate line CG1 503, connected to the PMOS transistor M1 531, is held at GND. This ground potential strongly influences the floating gate FG 570 via capacitive coupling, pulling the voltage of the floating gate itself down towards ground potential.

While the floating gate is held at a near-ground potential, the high voltage VPP is applied to the second control gate line CG2 505, which is connected to the PMOS transistor M2 533. This creates a large potential difference, and therefore a very strong electric field, across the gate oxide of the M2 533 transistor between the CG2 505 line and the nearly-grounded floating gate FG 570. This strong electric field is sufficient to overcome the energy barrier of the insulating oxide layer, repelling the negatively charged electrons trapped within the floating gate and causing them to tunnel out, as depicted in FIG. 5.

As electrons are expelled from the floating gate, its net charge becomes less negative (or more positive), which in turn lowers the threshold voltage (Vth) of the half-cell. Because this operation is applied globally, both floating gates FG 570 and FGB 590 are simultaneously erased, resetting both half-cells to a low-Vth state.

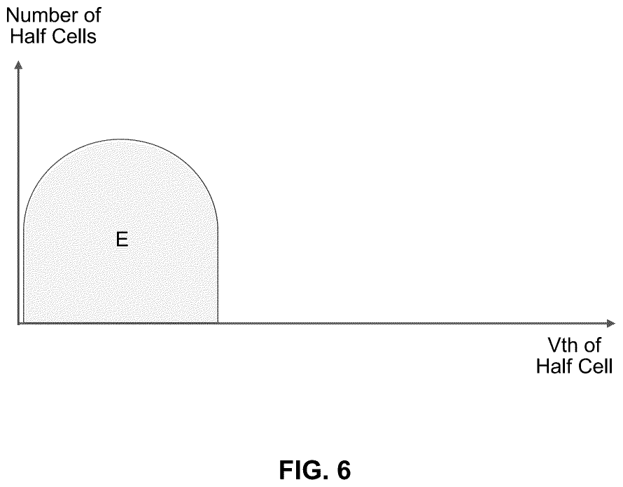

FIG. 6 is a graph illustrating the statistical distribution of the half-cell threshold voltages after the global erase operation of FIG. 5 has been performed. This distribution represents the ‘erased’ or reset state of the PUF cell array, which serves as the starting point for generating a new key. As described with reference to FIG. 5, the erase operation expels the trapped negative charges (electrons) from the floating gates of the half-cells. The removal of these electrons significantly lowers the threshold voltage (Vth) required to turn on the channel of the read transistor M3. With fewer negative charges on the floating gate to impede the formation of a conductive channel, a smaller positive voltage applied to the gate is now sufficient for the transistor to conduct current. Consequently, the entire Vth distribution for the population of half-cells is shifted significantly to the left along the x-axis, representing a collective low-Vth state, as depicted in FIG. 6. The letter ‘E’ inside the bell-shaped distribution denotes ‘Erased,’ indicating that this graph represents the Vth distribution of the half-cells in the erased state.

A critical aspect to note is that even after this uniform erase operation, the half-cells do not all converge to a single, identical Vth. The inherent, random physical variations from the manufacturing process, which gave rise to the initial distribution in FIG. 4, still persist in each cell. Each half-cell, having its own unique physical characteristics, responds slightly differently to the erase operation. As a result, the erased cells do not have a uniform Vth but rather exhibit a probabilistic spread around a new, very low mean value, thereby forming the distribution shown in FIG. 6. While most cells will have a Vth value near the center of this new distribution, a statistical variation still exists.

This remaining Vth variation in the globally erased state is fundamental to the ability of the PUF to be reprogrammed with a new, unique identity. Because a random Vth difference still exists between any pair of half-cells, a subsequent read operation will still produce a unique differential current, enabling the generation of a new random bit. This allows for a completely new key to be generated and hardened after the device has been reset to this erased state.

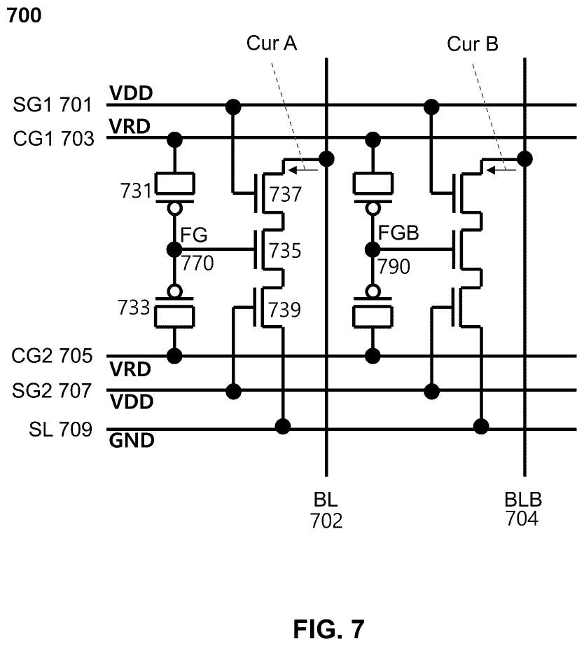

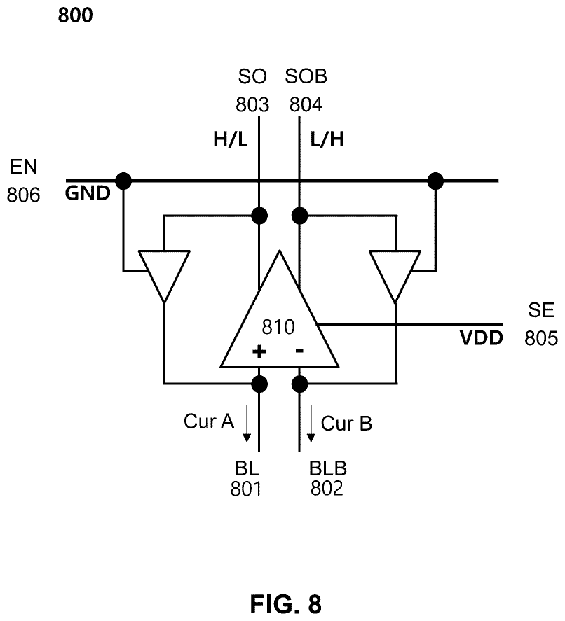

FIG. 7 illustrates the biasing conditions applied to the PUF cell 700 for a read operation performed on a cell in the erased state according to one embodiment of the invention. Following a global erase, this read operation serves to generate a new, unique random value. The purpose is to translate the unique physical characteristics, which persist even after erasing, into a measurable electrical difference. Specifically, this operation generates two slightly different cell currents, Cur A on the bit line BL 702 and Cur B on the complementary bit line BLB 704. The subsequent amplification and conversion of this current difference into a digital value are performed by the sensing circuit, which will be described with reference to FIG. 8.

To initiate a read operation on the PUF cell, a specific set of voltages is applied to the control and signal lines. The first and second select gate lines, SG1 701 and SG2 707, are both driven to a supply voltage VDD. This voltage level is sufficient to turn on the first select transistor S1 737 and the second select transistor S2 739 in both Half Cell A and Half Cell B. Concurrently, the common source line SL 709 is coupled to ground (GND). With the select transistors S1 737 and S2 739 turned on, a conductive path is established from the bit line BL 702 (and BLB 704) to the source line SL 709 through the series-connected NMOS transistors of each half-cell.

Simultaneously, a specific read reference voltage, VRD, is applied to both the first control gate line CG1 703 and the second control gate line CG2 705. This voltage is thereby applied to the source and drain terminals of the PMOS transistors M1 731 and M2 733 in both half-cells. The voltage VRD is capacitively coupled through these transistors to their respective floating gates, FG 770 and FGB 790, which in turn establishes a gate potential on the read transistors M3 735.

The core principle of generating a unique value from an erased state relies on the fact that the erase operation does not result in a perfectly uniform Vth for all cells. As established in the description of FIG. 6, a random Vth distribution persists even after erasing due to the inherent variations from the semiconductor manufacturing process. Consequently, the effective threshold voltage (Vth) of the read transistor M3 735 in Half Cell A will still be slightly different from that in Half Cell B.

Therefore, even though a similar gate potential is induced on both FG 770 and FGB 790 by the VRD voltage, the differing threshold voltages of the respective M3 735 transistors cause them to conduct electricity differently. This results in two distinct cell currents: Cur A flowing through the read path of Half Cell A to the bit line BL 702, and Cur B flowing through the read path of Half Cell B to the bit line BLB 704. This small, random, yet repeatable difference between Cur A and Cur B is the unique analog signature of the newly generated random bit from the erased PUF cell. This differential current is then passed to the sensing circuit for comparison and amplification.

### Sensing Operation Process

Referring to FIG. 8, the operational biasing of the sensing circuit 800 during a read or sense cycle is illustrated. FIG. 8 depicts the process of receiving the differential analog currents from a selected PUF cell and converting them into a stable, digital logic value. It should be noted that the sensing circuit 800 is the same as or similar to the sensing circuit 300 shown in FIG. 3. Here, the resulting half-cell currents (Cur A and Cur B) from the PUF cell, as generated during the read operation described in FIG. 7, are sensed differentially by the sensing circuit 800 to produce complementary digital outputs (SO 803 and SOB 804).

To activate the sensing operation, the sense enable signal SE 805 is driven to a high logic level, such as the supply voltage VDD. This enables the internal differential comparator (not shown) of the differential amplifier 810. Simultaneously, the enable signal EN 806 is held at a low logic level, such as ground (GND), which ensures that the feedback path of the circuit is disabled during the sensing phase. This prevents the outputs from interfering with the sensitive input signals on the BL 801 and BLB 802 lines.

With the sensing circuit 800 enabled, its primary function is to compare the magnitudes of the input currents, Cur A flowing from the bit line BL 801 and Cur B flowing from the complementary bit line BLB 802. As previously established, a minute, random difference will exist between Cur A and Cur B due to the intrinsic process variations of the PUF cell, even in its erased state.

The differential comparator (not shown) within the differential amplifier 810 detects this slight imbalance. This small difference is then amplified to a larger voltage swing, which is subsequently captured by the internal latch stage of the differential amplifier 810. The latch resolves this amplified signal into a full-swing, stable, and complementary digital output. For example, if the current Cur A is infinitesimally greater than Cur B, the sensing circuit 800 will drive the output SO 803 to a high logic level (‘H’) and the complementary output SOB 804 to a low logic level (‘L’). Conversely, if Cur B is greater than Cur A, SO 803 will be driven Low (‘L’) and SOB 804 will be driven High (‘H’).

Thus, FIG. 8 illustrates the critical step of reliably converting the unique, analog physical characteristic of an erased PUF cell into a stable, usable digital bit, which forms the basis of the new key generated by the PUF macro block.

A key challenge for PUF technology is ensuring the long-term reliability and stability of the generated bit. A small Vth difference, whether in its initial state or its erased state, can be susceptible to fluctuations from changing environmental conditions and device aging. Variations in temperature or supply voltage, as well as semiconductor aging effects, can compromise the integrity of the PUF output. To overcome this instability, the present invention employs a reprogramming or “hardening” process. Once a new random bit is generated from the erased state by the sensing circuit, this value is then used to actively program the PUF cell, intentionally creating a much larger and more robust Vth difference between the two half-cells.

### (Re)Programming or Hardening Operation Process

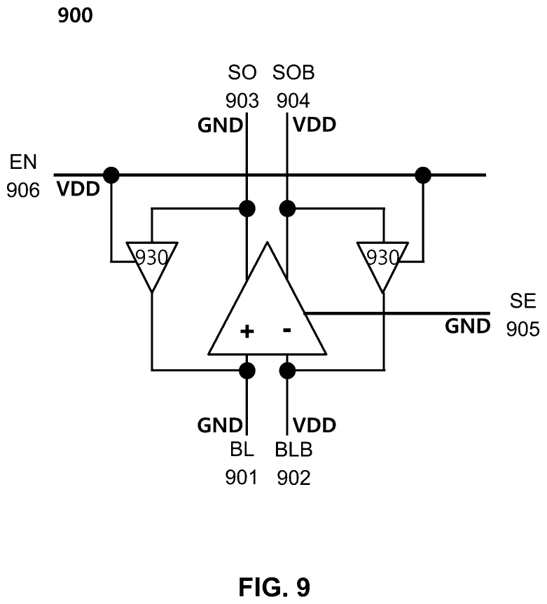

FIG. 9 illustrates the configuration of the sensing circuit 900 to initiate this reprogramming or hardening process by activating its feedback path. It should be noted that the sensing circuit 900 is the same as or similar to the sensing circuit 300 shown in FIG. 3. FIG. 9 shows the critical preparatory step where the digitally resolved state of the PUF cell is used to bias the bit lines to the precise voltage conditions on the bit lines required for the subsequent programming operation.

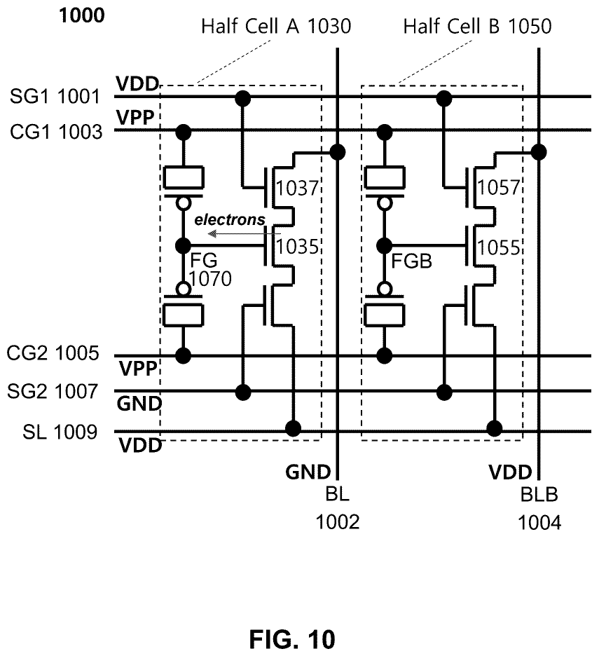

To enable this feedback mode, the enable signal EN 906 is driven to a high logic level, VDD. Concurrently, the sense enable signal SE 905 is set to a low logic level, GND, which deactivates the sensitive comparator stage. With EN 906 enabled and SE 905 disabled, the function of the differential amplifier 810 to compare and amplify the current difference between BL and BLB, as described in FIG. 8, is turned off. Instead, a feedback path is opened to deliver the digital voltages of SO 903 and SOB 904 back to the BL and BLB lines, respectively. For the purpose of this example, we assume the preceding sense operation (as in FIG. 8) determined that the current on BL 901 was less than on BLB 902, resulting in the latch storing a digital value of ‘0’ for SO 903 (GND) and ‘1’ for SOB 904 (VDD). With EN 906 activated, the buffers 930 in the feedback path are enabled, and the sensing circuit 900 actively drives these stored values back onto the bit lines, BL 901 and BLB 902. That is, the buffers 930 essentially function as switches, configured to disconnect the feedback path during the sense operation and to complete the feedback path during this feedback mode. Specifically, the low SO 903 output biases the bit line BL 901 to GND, while the high SOB 904 output biases the complementary bit line BLB 902 to VDD. These established voltage conditions are essential for the subsequent programming phase, as will be detailed next with reference to FIG. 10. Following the establishment of the bit line voltage conditions as described in FIG. 9, the PUF cell undergoes a selective programming operation.

FIG. 10 illustrates the specific biasing conditions applied to the PUF cell 1000 to perform this “hardening” operation. The goal is to translate the small, sensed Vth difference between the half-cells into a large and permanent Vth margin.

As established in the preceding step, the bit line BL 1002 is biased to GND and the bit line BLB 1004 is biased to VDD. While these conditions are maintained, a high programming voltage, VPP, is applied to both control gate lines CG1 1003 and CG2 1005. Simultaneously, SG1 1001 is driven to VDD, SG2 1007 is driven to GND, and the source line SL 1009 is driven to VDD.

In Half Cell A 1030 (the selected cell), the GND on BL 1002 and VDD on SG1 1001 turn on select transistor S1 1037. This creates a large electric field between the high-potential floating gate FG 1070 (influenced by VPP) and the grounded channel of the read transistor M3 1035, causing electrons to be injected into the floating gate 1070. This significantly increases the Vth of Half Cell A 1030.

In Half Cell B 1050 (the unselected cell), the VDD on BLB 1004 keeps the select transistor S1 1057 off. The channel of its read transistor M3 1055 becomes electrically isolated and is “self-boosted” to a high potential by capacitive coupling from the control gates. This reduces the electric field across the oxide, thus inhibiting the injection of electrons. As a result of this selective operation, Half Cell A 1030 is programmed to a high Vth state while Half Cell B 1050 remains in its low-Vth erased state, ‘hardening’ the newly generated random value into a stable physical state.

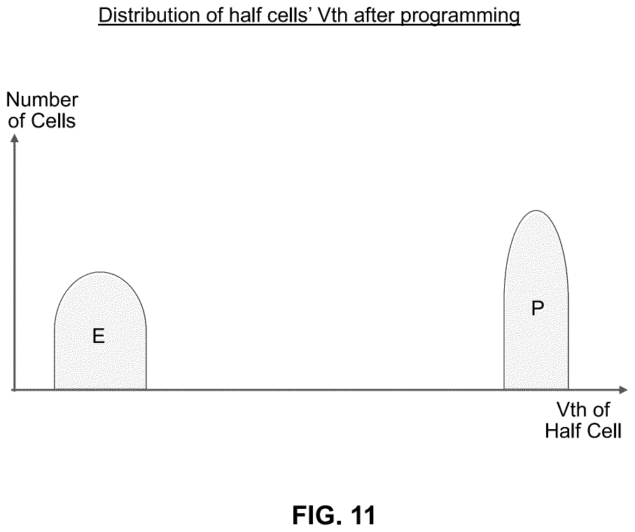

FIG. 11 is a conceptual graph illustrating the final, bimodal distribution of the half-cell threshold voltages after a full reprogrammable cycle is complete. This graph represents the stable, secure state in which the newly generated PUF key is stored. As a result of the hardening process, the half-cell population is now cleanly separated into two distinct, non-overlapping distributions: an Erased state (E) and a Programmed state (P).

The distribution on the left, labeled ‘E’, represents the half-cells that were program-inhibited and remain in the low-Vth erased state. As roughly half of the cells from the erased population (FIG. 6) were moved to the ‘P’ state, the peak height of the ‘E’ distribution is reduced, and its statistical spread may be narrower. The distribution on the right, labeled ‘P’, represents the half-cells that were selectively programmed. Their threshold voltages have been shifted to a significantly higher level. This ‘P’ distribution is characteristically narrow and sharply defined, as the programming operation drives the Vth of the selected cells towards a specific target.

The most critical outcome, illustrated in FIG. 11, is the wide, unambiguous Vth margin now established between the ‘E’ and ‘P’ states. This large, engineered separation ensures that the stored key is highly robust and resilient to noise from environmental factors. Should a new key be required in the future, the entire cycle of erasing (FIG. 5), reading (FIG. 7-8), and reprogramming (FIG. 9-10) can be repeated to generate a new, secure, and unique hardware identity.

A tempering attack on the PUF macro is an unwanted scenario since the randomly generated value is a security key that must be stored secretly. In one embodiment of the present invention, the PUF cell can be erased as illustrated in FIG. 5, and the new key can be generated as described in light of FIGS. 7-9. As already described, because of the inherent physical variations between half cells of the PUF cell, they will not erase identically. Indeed, each half cell can shift its original threshold voltage range by a different amount after the erase operation. When the half cells are erased, the differential conductance of each half cell within the PUF cell is altered, resulting in different output values from the associated sensing circuits. The sensing circuitry then reads these unique erased memory states. This reading is a measurement of the subtle differences in the erase process, which serves as a unique physical fingerprint for that specific memory cell.

Further, it should be noted that random noise from the comparator and latch in the sensing circuit can be utilized to ensure that the newly generated random value differs significantly from previously generated random keys. Then, the newly generated keys are hardened again as described with reference to FIG. 10. Based on the unique erased memory state, the proposed PUF circuitry selectively programs the sub-units. This programming is not random; it is directly controlled by the physical fingerprint measured in the previous step. The circuitry essentially translates the analog “erased memory state” into a permanent, non-volatile digital key. This results in unique patterns of programmed states across the sub-units, which are encoded into the final security key.

When necessary, the new key generation and hardening can be repeated. This makes the key extremely difficult to replicate, clone, or tamper with, as it relies on the device's intrinsic physical properties.

What is claimed is:

1. A non-volatile memory device comprising:
a memory cell array with a plurality of non-volatile memory cells;
a security key producing circuitry coupled to each column of the memory cell array, the security key producing circuitry configured to perform a series of erase, read, and program operations on a group of the plurality of memory cells to generate a device-specific security key of the memory device,
wherein the security key producing circuitry is configured to:
erase the group of the memory cells and read erased memory states varied by different physical processing variations of sub-units of each memory cell of the group; and
selectively program the sub-units of the erased memory cell based on the erased memory states of the sub-units such that resulting patterns of the programmed states of the erased sub-units are encoded into a permanent, non-volatile digital key.

2. The non-volatile memory device of claim 1, wherein the non-volatile memory cells are coupled to a plurality of input voltage lines and coupled to respective pairs of complementary bitlines, each memory cell including a pair of identical sub-units, each sub-unit including a pair of floating gates.

3. The non-volatile memory device of claim 2, wherein the pairs of complementary bitlines are connected to the security key producing circuitry.

4. The non-volatile memory device of claim 3, wherein the security key producing circuitry comprises a plurality of sensing circuits in parallel, each sensing circuit coupled to each column of the memory cell array.

5. The non-volatile memory device of claim 4, wherein each sensing circuit is configured to read states of sub-units in each memory cell through one of the pairs of complementary bit lines.

6. The non-volatile memory device of claim 5, wherein the sensing circuit is configured to detect which bitline in each pair of the complementary bit lines has a higher or a lower current value by comparing their current values relative to each other during a process of reading the sub-units of the erased memory cells.

7. The non-volatile memory device of claim 5, wherein said sensing circuit comprises:
a differential amplifier configured to convert a pair of current values of the complementary bitline into a pair of complementary digital values;
a pair of input paths for the differential amplifier to receive the pair of current values of the complementary bitlines;
a pair of output paths for the differential amplifier to output the pair of complementary digital values; and
a pair of buffer circuits between the input paths and the output paths, creating feedback paths for supplying the pair of complementary digital values to the complementary bitlines, wherein the feedback paths are configured to bias the complementary bitlines during a program operation, thereby selectively programming a first one of the pair of sub-units while inhibiting programming of a second one of the pair based on the complementary digital output signals.

8. The non-volatile memory device of claim 7, wherein the differential amplifier comprises:
a comparator configured to:
receive the pair of current values of the complementary bitlines connected to the sub-units within an associated said memory cell;
detect which one of the sub-units has a higher or lower current value; and
convert a pair of current values of the complementary bitlines coupled to the sub-units in each memory cell into corresponding digital values such that the sub-unit with a higher current value is converted into a digital logic “1”, and the sub-unit with a lower current value is converted into a digital logic “0”; and
a latch circuit configured to store the converted digital values of the sub-units of the memory cells.

9. The non-volatile memory device of claim 8, wherein the latch circuit is coupled to the pair of the output paths, outputting a binary 1 signal in response to the first input current signal greater than the second input current signal and outputting a binary 0 signal in response to the second input current signal lower than the first input current signal.

10. The non-volatile memory device of claim 7, wherein deactivated said buffer circuit pair prevents feedback of output signals to the inputs of the differential amplifier and allows inputting of currents flowing through complementary bitlines during the read operation.

11. The non-volatile memory device of claim 7, wherein activated said buffer circuit pair creates feedback loops for inputting the converted digital data values stored in the latch circuit to bias the complementary bitlines of the memory cell during the program operation.

12. In a non-volatile memory device having (1) a memory cell array with a plurality of nonvolatile memory cells in parallel, having their source electrodes coupled together into a combined source line, (2) pairs of complementary bitlines coupled to respective pairs of sub-units within each memory cell, and (3) a sensing device coupled to columns of the memory cell array, a method of creating a device-specific security key comprises:
(a) applying a set of predefined erase voltages to pairs of sub-units of a group of non-volatile memory cells in parallel;
(b) read erased memory states of the pair of sub-units by applying a set of predefined read voltages to the erased nonvolatile memory cells in parallel;
(c) comparing different current values of the pair of sub-units from the erased nonvolatile memory cells in parallel;
(d) programming a first sub-unit of the pair having a lower current value while preventing a second sub-unit of the pair having a higher current value from being programmed; and
(e) repeating (a) to (d) one or more times to create a permanent, non-volatile digital key.

13. The method of claim 12, wherein the step (b) is performed by a sensing device that comprises a group of sensing circuits in parallel coupled to respective columns of the memory cell array.

14. The method of claim 12, wherein the step (c) further comprises converting a pair of current values of the complementary bitline for each memory cell into a pair of corresponding complementary digital values.

15. The method of claim 12, wherein the step (d) includes converting a pair of current values of the complementary bitlines coupled to the sub-units in each memory cell into corresponding digital values such that the sub-unit with a higher current value is converted into a digital logic “1”, and the sub-unit with a lower current value is converted into a digital logic “0”.

16. The method of claim 15, wherein the step (d) further includes creating feedback paths for supplying the pair of complementary digital values to the complementary bitlines, wherein the feedback paths bias the pair of complementary bitlines during a program operation, thereby selectively programming a first one of the pair of sub-units while inhibiting programming of a second one of the pair based on the complementary digital output signals.

17. The method of claim 12, wherein each of the plurality of memory cells includes a floating gate.
